(19) United States
(12) Patent Application Publication
(10) Pub. No.: US 2013/0033823 A1
(43) Pub. Date: Feb. 7, 2013

(54) Electronic Control Unit

(71) Applicants: Kazuaki Nagashima, Kiryu-shi (JP); Ryota Takagi, Isesaki-shi (JP); Susumu Kaneko, Isesaki-shi (JP)

(72) Inventors: Kazuaki Nagashima, Kiryu-shi (JP); Ryota Takagi, Isesaki-shi (JP); Susumu Kaneko, Isesaki-shi (JP)

(73) Assignee: Hitachi Automotive Systems, Ltd., Hitachinaka-shi (JP)

(21) Appl. No.: 13/468,619

(22) Filed: May 10, 2012

(30) Foreign Application Priority Data
Aug. 5, 2011 (JP) 2011-171461

(51) Int. Cl. H05K 7/20

(52) U.S. Cl. 361/714

(57) ABSTRACT

An electronic control unit includes a casing, a circuit board, and a thermally conductive member. The circuit board is housed in and fixed to the casing. A heating element is mounted on the circuit board. The thermally conductive member is arranged between the casing and heating element for thermal conduction therebetween. The casing includes an internal surface including a contact section in intimate contact with the thermally conductive member. The contact section includes a projecting portion projecting toward the thermally conductive member. The projecting portion is located out of an area of the circuit board, wherein the heating element is located in the area. The heating element is mounted on one side of the circuit board. The thermally conductive member is fixed to another side of the circuit board, and located to face the heating element via the circuit board.

### BACKGROUND OF THE INVENTION

The present invention relates to an electronic control unit applicable to a vehicle anti-lock brake system, etc.

Japanese Patent Application Publication No. 2008-193108 discloses an electronic control unit for a motor vehicle. This electronic control unit includes: a casing made of aluminum alloy and having an upper cover and a lower cover; and a printed circuit board housed in the casing and arranged between the upper cover and the lower cover. The printed circuit board is provided with electrical parts constituting a control circuit, wherein the electrical parts are mounted on an upper side of the printed circuit board. The electrical parts include heating elements such as semiconductor switches and power ICs for driving actuators such as an electric motor and a solenoid.

The upper cover of the casing includes a projecting section projecting toward the printed circuit board. For cooling the heating elements, a thermally conductive sheet is arranged between the projecting section of the upper cover and the printed circuit board for thermal conduction therebetween. The thermally conductive sheet is located to face the heating elements, serving to effectively absorb heat of the heating elements. Under condition that the upper cover is attached to the lower cover to house the circuit board, a flat lower surface of the projecting section of the casing is in intimate contact with the upper surface of the thermally conductive sheet for enhancing the heat conductivity.

### SUMMARY OF THE INVENTION

In the construction described above, if the upper cover, lower cover, etc., has a large range of variation in the actual size, the thermally conductive sheet may be excessively compressed between the projecting section of the upper cover and the circuit board, to cause a large amount of local bending deformation of the circuit board, and thereby adversely affect the durability of the circuit board, and/or cause large stresses on the heating elements, and thereby adversely affect the life of soldering of terminals.

In view of the foregoing, it is desirable to provide an electronic control unit in which no such large stress is applied to a circuit board and heating elements.

According to one aspect of the present invention, an electronic control unit comprises: a casing; a circuit board housed in and fixed to the casing, wherein a heating element is mounted on the circuit board; and a thermally conductive member arranged between the casing and the heating element for thermal conduction between the casing and the heating element; wherein: the casing includes an internal surface including a contact section in intimate contact with the thermally conductive member, wherein the contact section includes a projecting portion projecting toward the thermally conductive member; and the projecting portion is located out of an area of the circuit board, wherein the heating element is located in the area. The electronic control unit may be configured so that: the heating element is mounted on a first side of the circuit board; and the thermally conductive member is fixed to a second side of the circuit board, and located to face the heating element via the circuit board, wherein the second side is opposite to the first side. The contact section may have a V-shape cross section whose apex constitutes the projecting portion. The contact section may have a pyramid-shape whose apex constitutes the projecting portion. The contact section may have an arc-shape cross section whose apex constitutes the projecting portion. The contact section may have a cone-shape whose apex constitutes the projecting portion. The electronic control unit may comprise at least two of the heating elements, wherein the projecting portion is located in an area of the circuit board between the two heating elements. The contact section may have an inclined surface whose distance from the circuit board gradually increases as followed away from the projecting portion.

### BRIEF DESCRIPTION OF THE DRAWINGS

FIG. 1 is an exploded perspective view of an electronic control unit according to a first embodiment of the present invention.

FIG. 2 is an enlarged cross-sectional view of the electronic control unit.

FIG. 3 is a plan view of the electronic control unit.

FIG. 4 is a cross-sectional view of the electronic control unit taken along the plane indicated by line A-A in FIG. 3.

FIG. 5 is a plan view of an electronic control unit according to a second embodiment of the present invention.

FIG. 6 is a cross-sectional view of the electronic control unit of FIG. 5 taken along the plane indicated by line B-B in FIG. 5.

FIGS. 7A and 7B are cross-sectional views of an electronic control unit according to a third embodiment of the present invention, where FIG. 7A shows a condition before a cover is attached to a fluid pressure control block, and FIG. 7B shows a condition after the cover is attached to the fluid pressure control block.

### DETAILED DESCRIPTION OF THE INVENTION

In first to third embodiments, an electronic control unit is applied to an anti-lock brake system (ABS) of a motor vehicle.

### First Embodiment

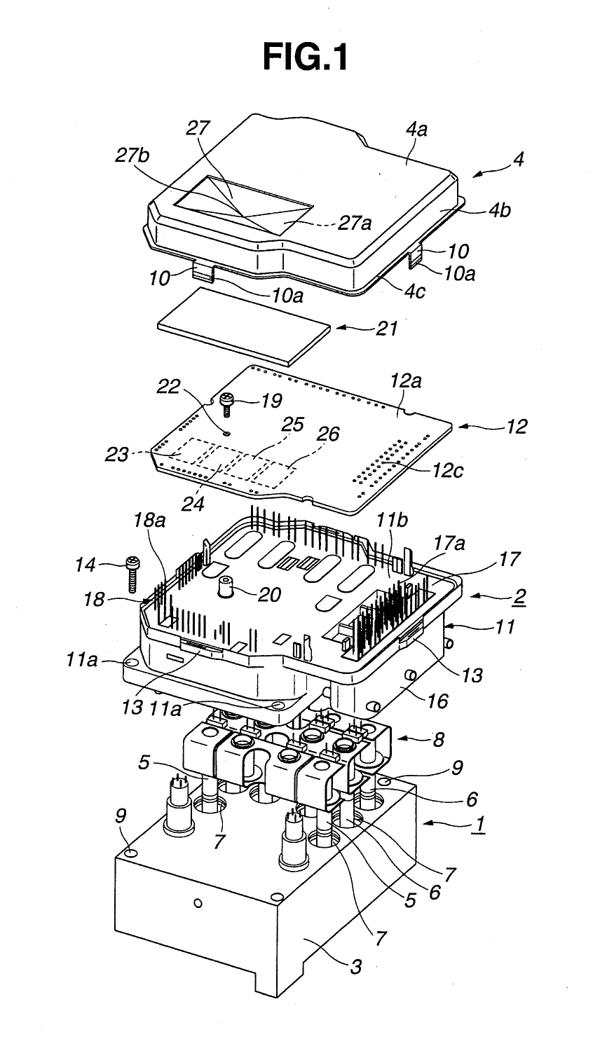

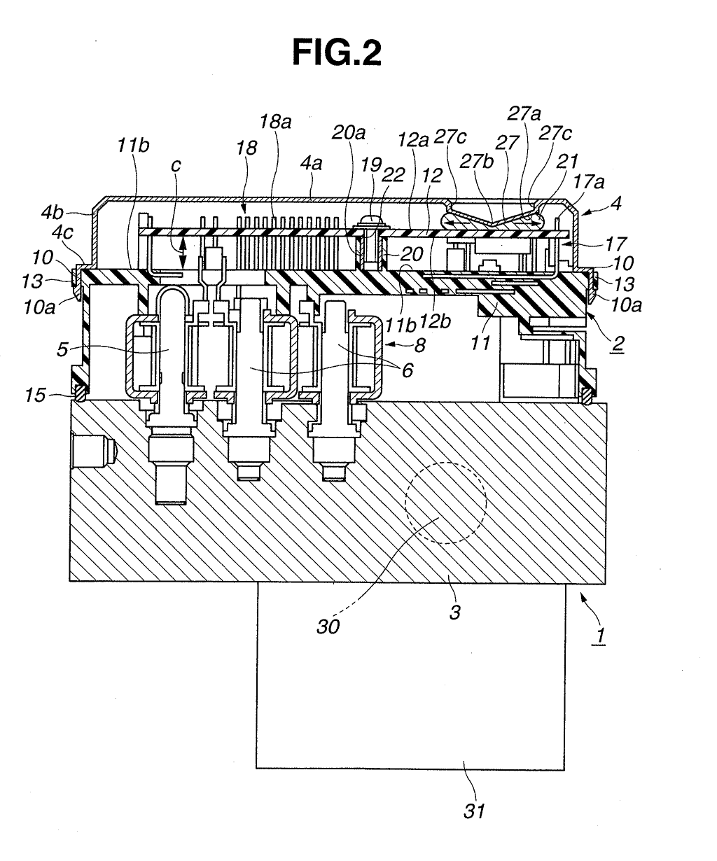

As shown in FIGS. 1 and 2, the anti-lock brake system includes a master cylinder not shown, a main passage not shown, pressure-increasing valves 5, pressure-reducing valves 6, a plunger pump 30, and a reservoir tank not shown. The master cylinder is configured to generate brake pressure depending on the amount of depression of a brake pedal. The main passage communicates the master cylinder to wheel cylinders of left and right front wheels and left and right rear wheels. Each valve 5, 6 is an electromagnetic valve provided in the main passage, which constitutes a fluid pressure control mechanism for controlling the brake pressure supplied from the master cylinder to the wheel cylinders. Each pressure-increasing valve 5 is a normally open solenoid valve, whereas each pressure-reducing valve 6 is a normally closed solenoid valve. Plunger pump 30 is provided in the main passage, and configured to pressurize and discharge brake fluid supplied to the wheel cylinders. The reservoir tank receives and stores brake fluid which is drained from the wheel cylinders through the pressure-reducing valves, and supplies brake fluid to the main passage by operation of plunger pump 30.

Plunger pump 30 may be replaced with a pump of another type, such as a gear pump.

In normal brake pedal operation mode, each pressure-increasing valve 5 is controlled to allow brake fluid to be supplied from the master cylinder to the corresponding wheel cylinder, whereas each pressure-reducing valve 6 is controlled to open to allow brake fluid to be drained to the reservoir tank in response to a condition that the internal pressure of the corresponding wheel cylinder exceeds a limit to cause the wheels to slip.

Pressure-increasing valves 5 and pressure-reducing valves 6 are opened and closed selectively by energization and de-energization in response to control signals under control operation of the electronic control unit so that the brake pressure of each wheel cylinder is increased, reduced, and maintained selectively.

The electronic control unit includes a casing 1 and an electronic control component part 2 as shown in FIGS. 1 and 2, wherein electronic control component part 2 is constituted by a plurality of electronic control components.

Casing 1 includes a fluid pressure control block 3 on a lower side and a cover 4 on an upper side. Cover 4 covers electronic control component part 2 from above, wherein electronic control component part 2 is mounted and attached to an upper side of fluid pressure control block 3.

Fluid pressure control block 3 is made of aluminum alloy, and is integrally formed, and has a substantially cubic form. Fluid pressure control block 3 has an upper surface from which a plurality of retaining holes 7 extend downward in a vertical direction in FIG. 1. Each retaining hole 7 houses and retains a lower side portion of corresponding pressure-increasing valve 5 or pressure-reducing valve 6. Fluid pressure control block 3 supports a coil unit 8 which is coupled to upper end portions of pressure-increasing valves 5 and pressure-reducing valves 6.

Fluid pressure control block 3 is formed with the main passage, an auxiliary passage, and a hydraulic unit. The hydraulic unit includes a plunger pump 30 and an electric motor 31. Plunger pump 30 is configured to supply brake pressure to the main passage. Electric motor 31 is configured to drive plunger pump 30. As shown in FIG. 1, the upper side of fluid pressure control block 3 is formed with internally threaded holes 9 at four corners, wherein fixing bolts not shown are screwed into internally threaded holes 9.

Cover 4 is made of aluminum alloy serving as a heat dissipating member (or heat sink), and has a dish-shape fitted to the outline of fluid pressure control block 3. Cover 4 is composed of a top wall 4a, a side wall 4b, and a flange 4c. Top wall 4a is generally flat. Side wall 4b is annular and formed integrally with the outside edge of top wall 4a. Flange 4c is formed integrally with the outside periphery of the lower edge portion of side wall 4b. Flange 4c is provided with a plurality of engaging projections 10 which extend downward from flange 4c in FIG. 1. When cover 4 is attached to a combination of a busbar unit 11 and a printed circuit board 12, each engaging projection 10 engages with the outside periphery of the upper side of busbar unit 11. Each engaging projection 10 is located substantially at the center of the corresponding edge of flange 4c. Each engaging projection 10 is formed with an engaging lug 10a at the outside periphery of the tip of engaging projection 10.

Electronic control component part 2 is arranged between fluid pressure control block 3 and cover 4, and configured to output switching signals for opening and closing operations of each pressure-increasing valve 5 or pressure-reducing valve 6. Electronic control component part 2 includes busbar unit 11 and printed circuit board 12. Busbar unit 11 includes a power electric circuit and an electromagnetic filtering circuit which are formed integrally. The power electric circuit is configured to supply electric power to the stator of electric motor 31. The electromagnetic filtering circuit is configured to suppress radio noise or electromagnetic noise. Printed circuit board 12 is arranged on the top of busbar unit 11, and configured to control operation of electric motor 31.

Busbar unit 11 is formed by molding a synthetic resin, and has a block shape. As shown in FIG. 1, the outline of busbar unit 11 is generally rectangular and fitted with the outlines of fluid pressure control block 3 and cover 4. Busbar unit 11 is provided with four engaging portions 13 at the outside periphery of the upper end section. Each engaging portion 13 has an insertion hole in which engaging lug 10a of engaging projection 10 of cover 4 extends and engages and is retained elastically. Busbar unit 11 is formed with a plurality of bolt insertion holes 11a at the corners of the outside periphery of busbar unit 11, through which a plurality of fixing bolts 14 are inserted.

On the other hand, as shown in FIG. 2, the outside periphery of the lower end section of busbar unit 11 includes an annular groove in which an annular seal 15 is mounted and fixed and is in elastic contact with the outside periphery of the top surface of fluid pressure control block 3.

A connector unit 16 is attached and fixed to a front end portion of busbar unit 11. Connector unit 16 includes a power connector, a motor connector and a signal connector. The power connector is adapted for connection to a battery. The motor connector is adapted for connection to electric motor 31 for power supply. The signal connector is adapted for connection to a resolver, a CAN communication line, and an I/O interface for transmission of various signals.

The external surface and inside of busbar unit 11 is provided with many power distribution patterns for a power supply negative side busbar and a power supply positive side busbar which are connected to the power connector, and a busbar for output to the motor, etc.

Busbar unit 11 is provided with a terminal section 17 and a terminal section 18 at an upper surface 11b. Terminal section 17 includes a plurality of terminals connected to the power connector, motor connector and signal connector, wherein the terminals extend upward from upper surface 11b as shown in FIG. 1. Terminal section 18 includes a plurality of terminals for control signals for driving motor relays and semiconductor switch elements (FET), wherein the terminals extend upward from upper surface 11b.

Busbar unit 11 is also provided with various electrical components at a lower surface 11b. The electrical components include electrical components of the power electric circuit and electrical components of the filtering electric circuit, such as aluminum electrolytic capacitors, normal mode choke coils, common mode choke coils, and ceramic capacitors.

The upper surface 11b of busbar unit 11 is formed integrally with a cylindrical portion 20 which printed circuit board 12 is fixed to and supported by through a screw 19. Cylindrical portion 20 is located close to a thermally conductive sheet 21 that is bonded to the upper surface 12a of printed circuit board 12. A cylindrical member 20a is made of metal and is fixed to the inside periphery of cylindrical portion 20. Cylindrical member 20a is formed with an internal thread at an inside surface, wherein screw 19 is screwed with the internal thread of cylindrical member 20a.

Printed circuit board 12 is made of synthetic resin and has a substantially square sheet shape. Printed circuit board 12 is formed with a screw insertion hole 22 which extends through the thickness of printed circuit board 12, and faces cylindrical portion 20 of busbar unit 11, and is relatively close to the center of printed circuit board 12. When printed circuit board 12 is mounted from above to busbar unit 11, the lower side edge of screw insertion hole 22 is brought into contact with the upper surface of cylindrical portion 20 so that the height of cylindrical portion 20 serves to provide a vertical clearance C therebetween, and thereby prevent the electrical components from interfering with each other.

Printed circuit board 12 is provided with a plurality of electrical components such as a microcomputer, and provided with a power distribution pattern inside of printed circuit board 12, which constitutes a control circuit. Printed circuit board 12 generates control signals for controlling an inverter which serves as a drive circuit for driving the electric motor 31.

Semiconductor switch elements (MOS-FETs) 23, 24, 25, 26 are arranged and fixed on the lower surface 12b of printed circuit board 12 as shown in FIGS. 2 to 4, wherein semiconductor switch elements 23, 24, 25, 26 are heating elements to be cooled.

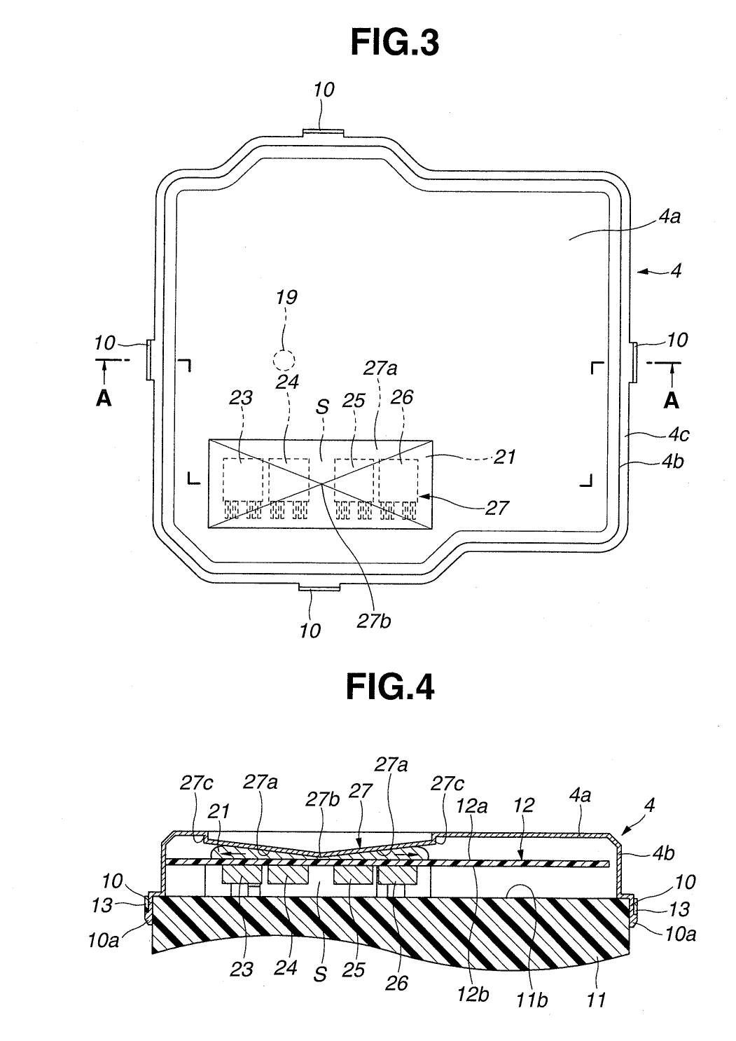

As shown in FIGS. 3 and 4, semiconductor switch elements 23, 24, 25, 26 are aligned in a lateral direction of printed circuit board 12, and fixed with their upper surfaces in intimate contact with the lower surface 12b of printed circuit board 12. Two central adjacent semiconductor switch elements 24 and 25 (central in the lateral direction) define a clearance S therebetween, so that the pair of semiconductor switch elements 23, 24 and the pair of semiconductor switch elements 25, 26 are separated from each other by clearance S as shown in FIG. 3.

Thermally conductive sheet 21 is bonded to the upper surface 12a of printed circuit board 12, and is located at the position where semiconductor switch elements 23, 24, 25, 26 are arranged. Thermally conductive sheet 21 has a substantially rectangular shape extending in the direction where semiconductor switch elements 23, 24, 25, 26 are arranged. Thermally conductive sheet 21 is made of an elastic insulating material.

Printed circuit board 12 includes a plurality of terminal insertion holes 12c which are formed at the periphery of printed circuit board 12, namely, at left and right lateral end portions of printed circuit board 12 as shown in FIG. 1. Each terminal insertion hole 12c allows a terminal pin 17a of terminal section 17 or terminal pin 18a of terminal section 18 of busbar unit 11 to pass through, wherein terminal pins 17a and terminal pins 18a are connected and fixed by soldering.

The top wall 4a of cover 4 includes a projecting section 27 at a position facing the thermally conductive sheet 21 on printed circuit board 12. Projecting section 27 projects downward from the remaining part of the top wall 4a, and is adapted to be in intimate contact with thermally conductive sheet 21.

When cover 4 is attached and fixed to busbar unit 11 to cover the printed circuit board 12, the lower surface 27a of projecting section 27 is brought into slightly pressing contact with the entire top surface of thermally conductive sheet 21. Projecting section 27 has a pyramid shape projecting downward, wherein lower surface 27a is constituted by four triangle surfaces. Each triangle surface to is inclined downward from the periphery to the center, so that the lower surface 27a has V-shaped cross-sections along any plane passing through an apex or projecting portion 27b of the pyramid shape of lower surface 27a at the center of lower surface 27a. The projecting portion 27b is located substantially at the center of thermally conductive sheet 21, and is in pressing contact with the center of thermally conductive sheet 21. Namely, projecting portion 27b of cover 4 is arranged to press the position of clearance S (preferably, the position of the central portion of clearance S) between the pair of semiconductor switch elements 23, 24 and the pair of semiconductor switch elements 25, 26.

<Assembling Operation>

The following describes an assembling operation for the electronic control unit described above. Before total assembling, several groups of components are assembled first as follows. Pressure-increasing valves 5, pressure-reducing valves 6, plunger pump 30, electric motor 31, the reservoir, etc., are attached to fluid pressure control block 3, forming the hydraulic unit. The power distribution patterns of the power electric circuit and the power distribution patterns of the filtering electric circuit are integrated in a module, and the module and busbar unit 11 are integrated together. Also, the electrolytic capacitors and the other electrical components are attached to busbar unit 11. Moreover, the power distribution patterns of printed circuit board 12 and semiconductor switch elements 23, 24, 25, 26 are attached to printed circuit board 12.

Next, printed circuit board 12 is placed on busbar unit 11 with the periphery of the lower side opening of screw insertion hole 22 of printed circuit board 12 in contact with the top surface of cylindrical portion 20 of busbar unit 11. Simultaneously, terminal pins 17a and terminal pins 18a are inserted into corresponding terminal insertion holes 12c of printed circuit board 12.

Thereafter, screw 19 is inserted through the screw insertion hole 22 into the internal thread portion of cylindrical member 20a of cylindrical portion 20, thus fixing the printed circuit board 12 to the busbar unit 11. Then, terminal pins 17a and terminal pins 18a are fixed to printed circuit board 12 by soldering under condition that terminal pins 17a and terminal pins 18a are inserted in terminal insertion holes 12c as described above. Electrical coupling therebetween is thus established.

Then, as shown in FIG. 2, an adhesive is applied to the outside periphery of cover 4, and cover 4 is placed over printed circuit board 12 and busbar unit 11, and each engaging lug 10a of engaging projection 10 is inserted and engaged with corresponding engaging portion 13 of busbar unit 11 while engaging lug 10a is elastically deformed. The engagement therebetween makes it easy to attach cover 4 to busbar unit 11.

After the foregoing assembling operation, the busbar unit 11 is positioned and mounted on the top surface of fluid pressure control block 3 via the annular seal 15, and then busbar unit 11 is fixed to fluid pressure control block 3 with fixing bolts 14. The assembling operation is thus finished.

Under the assembled condition, the projecting portion 27b of projecting section 27 of cover 4 presses the substantially central portion of thermally conductive sheet 21. The pressing force results in forces in lateral directions outwardly from the projecting portion 27b as indicated by arrows in FIGS. 2 and 4, wherein the inclined lower surfaces 27a around the projecting portion 27b press and deform the contact surfaces of thermally conductive sheet 21 outwardly in the lateral directions. The downward pressing force is thus distributed outwardly.

The above feature serves to significantly reduce the pressing force between thermally conductive sheet 21 and printed circuit board 12 while maintaining a suitable pressure between thermally conductive sheet 21 and projecting section 27 for suitable intimate contact therebetween. In other words, the pressing force varies according to the amount of escape or the degree of freedom of movement of thermally conductive sheet 21 so that the pressing force at the center of thermally conductive sheet 21 facing the projecting portion 27b is maximal because escaping movement of the compressed portion of thermally conductive sheet 21 at that position is substantially prevented, whereas the pressing force gradually decreases as followed from the projecting portion 27b toward semiconductor switch elements 23, 26 because thermally conductive sheet 21 is released from compression at the periphery of projecting section 27, i.e. thermally conductive sheet 21 can escape from pressing force. The provision of the inclined lower surface 27a in projecting section 27 achieves in this way that the compressed thermally conductive sheet 21 escapes or moves or deforms from the pressure point of projecting portion 27b along the inclined lower surface 27a so that the pressing force decreases and is distributed. This suppresses undesirable deformation of semiconductor switch elements 23, 24, 25, 26 and printed circuit board 12. The lower surface 27a serves as a means for allowing the compressed thermally conductive sheet 21 to escape from the center and preventing undesirable deformation of printed circuit board 12.

The above feature serves to suppress partial or local deformation of printed circuit board 12, and suppress stresses applied to semiconductor switch elements 23, 24, 25, 26. As a result, it is possible to suppress adverse effects of the pressing force applied to printed circuit board 12 and semiconductor switch elements 23, 24, 25, 26, and enhance the durability of printed circuit board 12 and semiconductor switch elements 23, 24, 25, 26.

The further feature that the pressing force is not directly applied to semiconductor switch elements 23, 24, 25, 26, but applied to the portion of clearance S between the pair of semiconductor switch elements 23, 24 and the pair of semiconductor switch elements 25, 26, further serves to reduce the stresses applied to semiconductor switch elements 23, 24, 25, 26.

The arrangement that printed circuit board 12 is fixed and supported by the combination of screw 19 and cylindrical portion 20 at or close to thermally conductive sheet 21, serves to enhance the strength of printed circuit board 12 at that place, and suppress deformation due to the pressing force from projecting section 27 to thermally conductive sheet 21, and thereby suppress stresses applied to semiconductor switch elements 23, 24, 25, 26. This advantageous effect is enhanced by the feature that the overall pressing force is suppressed as described above.

In the present embodiment, thermally conductive sheet 21 is placed on the upper surface (back surface) of printed circuit board 12, whereas semiconductor switch elements 23, 24, 25, 26 are mounted on the lower surface of printed circuit board 12. Accordingly, heat generated by semiconductor switch elements 23, 24, 25, 26 is transmitted to the upper surface of printed circuit board 12 thorough the heat sink and via holes for thermal conduction.

In terms of heat dissipation, it is advantageous that thermally conductive sheet 21 is placed on the upper surface of printed circuit board 12 that is opposite to the surface where semiconductor switch elements 23, 24, 25, 26 are placed. As compared to cases where thermally conductive sheet 21 is placed on the surface where semiconductor switch elements 23, 24, 25, 26 are placed, the arrangement of this embodiment is advantageous because the flatness of the surface between thermally conductive sheet 21 and semiconductor switch elements 23, 24, 25, 26 causes little clearance or air layer therebetween, wherein the air layer is disadvantageous in terms of thermal conduction.

Moreover, in terms of deformation of semiconductor switch elements 23, 24, 25, 26 due to pressing force, the feature that thermally conductive sheet 21 is mounted to the side of printed circuit board 12 that is opposite to the soldered portions of semiconductor switch elements 23, 24, 25, 26 with respect to printed circuit board 12, serves to suppress adverse effects of the pressing force from projecting section 27 on the soldered portions, and thereby suppress adverse effects (disconnection, etc.) on the electrical connections of semiconductor switch elements 23, 24, 25, 26. The soldered portions are soldered portions for connection between semiconductor switch elements 23, 24, 25, 26 and printed circuit board 12, or soldered portions for connection between semiconductor switch elements 23, 24, 25, 26 and the heat sink when semiconductor switch elements 23, 24, 25, 26 are connected to printed circuit board 12 through the heat sink.

The feature that thermally conductive sheet 21 is located in the position corresponding to plunger pump 30 or electric motor 31, serves to absorb vibration by thermally conductive sheet 21, wherein such vibration can be generated in fluid pressure control block 3 or cover 4 due to vibration of plunger pump 30. In this way, the present embodiment also prevents printed circuit board 12 from being adversely affected by vibrations.

The feature that the power distribution patterns of the power electric circuit and the filtering electric circuit are gathered in a module, and the module and busbar unit 11 are integrated together, serves to reduce the vertical size of the electronic control unit, and thereby make the entire electronic control unit compact and light in weight.

The feature that suitable intimate contact between thermally conductive sheet 21 and projecting section 27 is maintained, serves to allow cover 4 to absorb efficiently the heat generated by semiconductor switch elements 23, 24, 25, 26.

The feature that cover 4 can be easily attached to busbar unit 11 by engagement between engaging projections 10 and engaging portions 13, serves to make it easy to attach cover 4.

Projecting section 27 of cover 4 can be formed simultaneously with drawing formation of cover 4, which also serves to make it easy or simple to form the cover 4.

### Second Embodiment

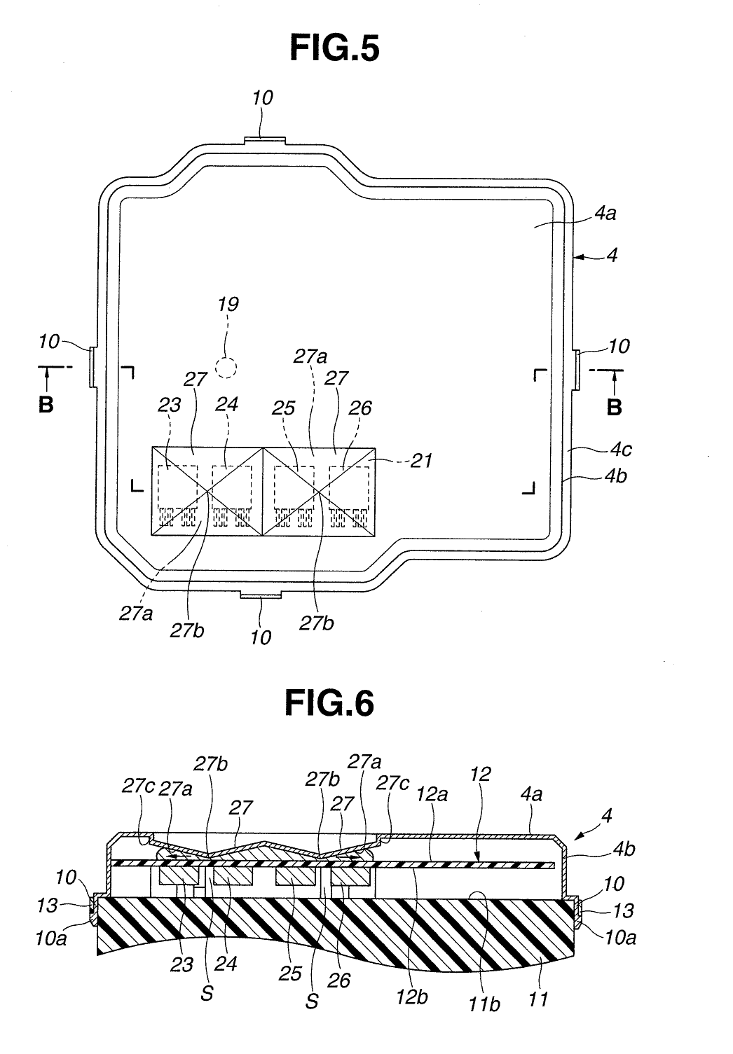

FIGS. 5 and 6 show an electronic control unit according to a second embodiment of the present invention. In this embodiment, semiconductor switch elements 23, 24, 25, 26 are mounted on the lower surface 12b of printed circuit board 12, and arranged in a row at substantially even intervals. On the other hand, cover 4 is formed with two projecting sections 27. Each projecting section 27 has a pyramid shape, so that projecting sections 27 have a wave form (W-shape) cross section taken along a vertical plane as shown in FIG. 6. Namely, the lower surfaces 27a of each projecting section 27 are inclined as followed laterally from a projecting portion 27b at the center of projecting section 27. Each projecting portion 27b is located at a clearance S between semiconductor switch elements 23 and 24 or between semiconductor switch elements 25 and 26. Preferably, each projecting portion 27b is located at the center of clearance S between semiconductor switch elements 23 and 24 or between semiconductor switch elements 25 and 26. Except the foregoing, the electronic control unit of the second embodiment has the same configuration as in the first embodiment.

The second embodiment produces similar advantageous effects as the first embodiment. The provision of two projecting sections 27b results in that thermally conductive sheet 21 is subject to pressing force at two points so that each pressing force at projecting portion 27b is slightly larger than the pressing force in the first embodiment. However, each pressing force at projecting portion 27b is distributed by the inclined lower surfaces 27a of each projecting section 27, so that the entire pressing force applied to printed circuit board 12 is suppressed.

In this way, the second embodiment is effective for suppressing partial bending deformation of printed circuit board 12, and suppressing stresses applied to semiconductor switch elements 23, 24, 25, 26. The feature that projecting portions 27b are located at corresponding clearances S between semiconductor switch elements 23, 24 and between semiconductor switch elements 25, 26, serves to significantly suppress the applied stresses.

The feature that each projecting section 27 is provided with rib 27c at the connection between projecting section 27 and the other part of cover 4, serves to reinforce the cover 4 as in the first embodiment.

### Third Embodiment

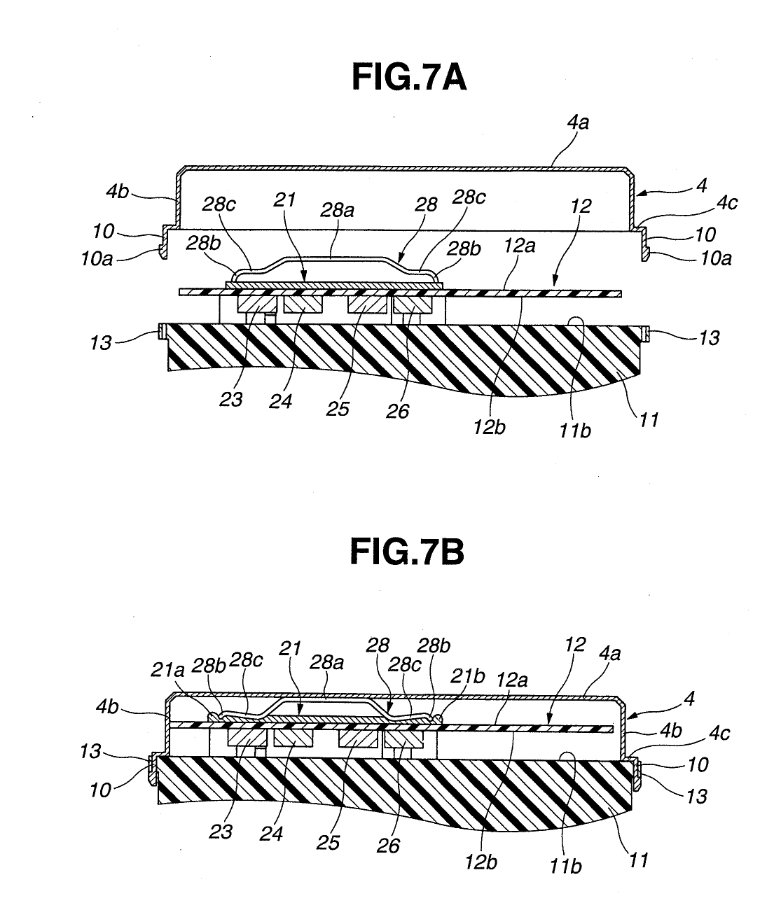

FIGS. 7A and 7B show an electronic control unit according to a third embodiment of the present invention. In this embodiment, the arrangement of semiconductor switch elements 23, 24, 25, 26 on the lower surface 12b of printed circuit board 12 is the same as in the first embodiment. In particular, a spring member 28 is provided separately from cover 4, wherein spring member 28 is elastically deformable.

Specifically, spring member 28 is made of a thermally conductive metal sheet, and formed by press forming into a rectangular shape extending longitudinally of thermally conductive sheet 21. Spring member 28 includes a top portion 28a, a pair of leg portions 28b, 28b, and a pair of contact portions 28c. Top portion 28a is substantially flat. Each leg portion 28b extends downward from one end of top portion 28a. Contact portion 28c is connected between top portion 28a and leg portion 28b, and is adapted to be in intimate contact with the upper surface of thermally conductive sheet 21. Each leg portion 28b is in engaging contact with a longitudinal end portion 21a or 21b of thermally conductive sheet 21, wherein the position of contact is sufficiently out of the position of semiconductor switch elements 23, 24, 25, 26.

Cover 4 is attached to busbar unit 11 as follows. First, as shown in FIG. 7A, leg portions 28b, 28b of spring member 28 are brought into contact with first and second longitudinal end portions 21a, 21b of thermally conductive sheet 21. Then, as shown in FIG. 7B, cover 4 is pressed down and attached to busbar unit 11 with engagement between engaging projections 10 and engaging portions 13. Simultaneously, the top wall 4a of cover 4 is pressed down onto the upper surface of top portion 28a of spring member 28, so that each leg portion 28b is depressed and deformed elastically and thereby engaged with the upper surface of thermally conductive sheet 21. The pressing force acts on thermally conductive sheet 21 in the direction to move the first and second longitudinal end portions 21a, 21b away from each other. Under this condition, top portion 28a of spring member 28 is out of contact with thermally conductive sheet 21, although top portion 28a serves to press the leg portions 28b, 28b onto the upper surface of thermally conductive sheet 21.

According to the construction described above, thermally conductive sheet 21 is subject to an elastic pressing force from spring member 28, and particularly, only first and second longitudinal end portions 21a, 21b of thermally conductive sheet 21 are subject to the pressing force from leg portions 28b, 28b. This pressing force is sufficiently small, which serves to suppress bending deformation of printed circuit board 12. On the other hand, semiconductor switch elements 23, 24, 25, 26 are not subject to a pressing force directly from leg portions 28b, 28b, which serves to reduce stresses applied to semiconductor switch elements 23, 24, 25, 26.

The heat transmitted from semiconductor switch elements 23, 24, 25, 26 to thermally conductive sheet 21 through the printed circuit board 12 is then transmitted to cover 4 through the spring member 28. In this way, efficient heat dissipation is achieved.

The feature that spring member 28 is simply formed from a metal sheet by press forming, serves to simplify the manufacturing process, and thereby reduce the manufacturing cost.

The first to third embodiments described above may be modified. For example, projecting section 27 may have a cone shape or an arc-shape cross-section, instead of a pyramid shape. Heating elements to be cooled may be power ICs instead of or in addition to semiconductor switch elements 23, 24, 25, 26. The number of semiconductor switch elements is not limited to four but may be more or less than four.

The thickness of thermally conductive sheet 21 may be adjusted to finely adjust the pressing force from cover 4.

The shape and structure of casing 1 or those of busbar unit 11 may be changed arbitrarily as appropriate. Although the electronic control unit is applied to the ABS system in the present embodiments, it may be applied to another system such as an electric power steering system.

Fluid pressure control block 3 may be made of a synthetic resin.

The entire contents of Japanese Patent Application 2011-171461 filed Aug. 5, 2011 are incorporated herein by reference.

Although the invention has been described above by reference to certain embodiments of the invention, the invention is not limited to the embodiments described above. Modifications and variations of the embodiments described above will occur to those skilled in the art in light of the above teachings. The scope of the invention is defined with reference to the following claims.

What is claimed is:

1. An electronic control unit comprising:
a casing;
a circuit board housed in and fixed to the casing, wherein a heating element is mounted on the circuit board; and
a thermally conductive member arranged between the casing and the heating element for thermal conduction between the casing and the heating element;
wherein:
the casing includes an internal surface including a contact section in intimate contact with the thermally conductive member, wherein the contact section includes a projecting portion projecting toward the thermally conductive member; and
the projecting portion is located out of an area of the circuit board, wherein the heating element is located in the area.

2. The electronic control unit as claimed in claim 1, wherein the contact section has a V-shape cross section whose apex constitutes the projecting portion.

3. The electronic control unit as claimed in claim 1, wherein the contact section has a pyramid-shape whose apex constitutes the projecting portion.

4. The electronic control unit as claimed in claim 1, wherein the contact section has an arc-shape cross section whose apex constitutes the projecting portion.

5. The electronic control unit as claimed in claim 1, wherein the contact section has a cone-shape whose apex constitutes the projecting portion.

6. The electronic control unit as claimed in claim 1, comprising at least two of the heating elements, wherein the projecting portion is located in an area of the circuit board between the two heating elements.

7. The electronic control unit as claimed in claim 1, wherein the contact section has an inclined surface whose distance from the circuit board gradually increases as followed away from the projecting portion.

8. The electronic control unit as claimed in claim 1, wherein:
the heating element is mounted on a first side of the circuit board; and
the thermally conductive member is fixed to a second side of the circuit board, and located to face the heating element via the circuit board, wherein the second side is opposite to the first side.

9. The electronic control unit as claimed in claim 8, wherein the contact section has a V-shape cross section whose apex constitutes the projecting portion.

10. The electronic control unit as claimed in claim 8, wherein the contact section has a pyramid-shape whose apex constitutes the projecting portion.

11. The electronic control unit as claimed in claim 8, wherein the contact section has an arc-shape cross section whose apex constitutes the projecting portion.

12. The electronic control unit as claimed in claim 8, wherein the contact section has a cone-shape whose apex constitutes the projecting portion.

13. The electronic control unit as claimed in claim 8, comprising at least two of the heating elements, wherein the projecting portion is located in an area of the circuit board between the two heating elements.

14. The electronic control unit as claimed in claim 8, wherein the contact section has an inclined surface whose distance from the circuit board gradually increases as followed away from the projecting portion.
